(19) United States
(12) Patent Application Publication
(10) Pub. No.: US 2008/0283827 A1
(43) Pub. Date: Nov. 20, 2008

(54) FUSED-FLUORENE-CONTAINING MATERIALS AS SEMICONDUCTOR MATERIALS FOR THIN FILM TRANSISTORS

(76) Inventors: Shiying Zheng, Webster, NY (US); Diane C. Freeman, Pittsford, NY (US)

Correspondence Address: Andrew J. Anderson;Patent Legal Staff, Eastman Kodak Company, 343 State Street, Rochester, NY, 14650-2201, US

(21) Appl. No.: 11/748,640

(22) Filed: May 15, 2007

(51) Int. Cl. H01L 51/30; H01L 51/40

(52) U.S. Cl. 257/40; 438/99; 257/E51.006; 257/E51.012; 257/E51.018; 257/E51.028; 257/E51.032

(57) ABSTRACT

A thin film transistor comprises a layer of organic semiconductor material comprising an organic semiconductor material that comprises fused-fluorene-containing materials. Such transistors can further comprise spaced apart first and second contact means or electrodes in contact with said material. Further disclosed is a process for fabricating a thin film transistor device, preferably by sublimation or solution-phase deposition onto a substrate, wherein the substrate temperature is no more than 150° C.

### FIELD OF THE INVENTION

The present invention relates to the use of fused-fluorene-containing material as semiconductor materials for thin film transistors. The invention relates to the use of these materials in thin film transistors for electronic devices and methods of making such transistors and devices.

### BACKGROUND OF THE INVENTION

Thin film transistors (TFTs) are widely used as a switching element in electronics, for example, in active-matrix liquid-crystal displays, smart cards, and a variety of other electronic devices and components thereof. The thin film transistor (TFT) is an example of a field effect transistor (FET). The best-known example of an FET is the MOSFET (Metal-Oxide-Semiconductor-FET), today's conventional switching element for high-speed applications. Presently, most thin film devices are made using amorphous silicon as the semiconductor. Amorphous silicon is a less expensive alternative to crystalline silicon. This fact is especially important for reducing the cost of transistors in large-area applications. Application of amorphous silicon is limited to low speed devices, however, since its maximum mobility (0.5-1.0 cm²/Vsec) is about a thousand times smaller than that of crystalline silicon.

Although amorphous silicon is less expensive than highly crystalline silicon for use in TFTs, amorphous silicon still has its drawbacks. The deposition of amorphous silicon, during the manufacture of transistors, requires relatively costly processes, such as plasma enhanced chemical vapor deposition and high temperatures (about 360° C.) to achieve the electrical characteristics sufficient for display applications. Such high processing temperatures disallow, for deposition, the use of substrates made of certain plastics desirable for applications such as flexible displays.

In the past decade, organic materials have received attention as a potential alternative to inorganic materials such as amorphous silicon for use in semiconductor channels of TFTs. Organic semiconductor materials are simpler to process, especially those that are soluble in organic solvents and, therefore, capable of being applied to large areas by far less expensive processes, such as spin coating, dip coating and microcontact printing. Furthermore, organic materials may be deposited at lower temperatures, opening up a wider range of substrate materials, including plastics, for flexible electronic devices. Accordingly, thin film transistors made of organic materials can be viewed as a potentially important technology for plastic circuitry in display drivers, portable computers, pagers, memory elements in transaction cards, and identification tags, where ease of fabrication or mechanical flexibility is advantageous.

Organic semiconductor materials that can be used in TFTs to provide the switching and/or logic elements in electronic components require significant mobilities, at least 0.01 cm²/Vs, and current on/off ratios (hereinafter referred to as “on/off ratios”) greater than 1000. Organic TFTs having such properties are capable of use for electronic applications such as pixel drivers for displays and identification tags. Most of the compounds exhibiting these desirable properties are “p-type” or “p-channel,” meaning that negative gate voltages, relative to the source voltage, are applied to induce positive charges (holes) in the channel region of the device. N-type organic semiconductor materials can be used in TFTs as an alternative to p-type organic semiconductor materials, where the terminology “n-type” or “n-channel” indicates that positive gate voltages, relative to the source voltage, are applied to induce negative charges in the channel region of the device.

The performance of the device is principally based upon the charge carrier mobility of the semiconducting material and the current on/off ratio, so the ideal semiconductor should have a low conductivity in the off state, combined with a high charge carrier mobility (>1×10⁻³ cm² V s⁻¹). In addition, it is important that the semiconducting material is relatively stable to oxidation, i.e., it has a high ionization potential, as oxidation leads to reduced device performance.

A well-known compound which has been shown to be an effective p-type semiconductor for OFETs is pentacene (see Nelson et al., Appl. Phys. Lett., 1998, 72, 1854). When deposited as a thin film by vacuum deposition, it was shown to have carrier mobilities in excess of 1 cm² V⁻¹ s⁻¹ with very high current on/off ratios greater than 10⁶.

Regioregular poly(3-hexylthiophene) has been reported with charge carrier mobility between 1×10⁻⁵ and 4.5×10⁻² cm² V⁻¹ s⁻¹, but with a rather low current on/off ratio (10-10³), by Bao et al. in Appl. Phys. Lett., 1996, 69, 4108. In general, poly(3-alkylthiophenes) show good solubility and are able to be solution processed to fabricate large area films. However, poly(3-alkylthiophenes) have relatively low ionization potentials and are susceptible to doping in air (see Sirringhaus et al. Adv. Solid State Phys., 1999, 39, 101).

U.S. Pat. No. 6,452,207 to Bao discloses fluorene-based oligomers for use in organic semiconductors and thin film transistors. Bao's materials were found to have relatively high band gasp and low HOMO levels. The materials did not require crystallographic alignment to give good electrical performance. Thiophene rings were incorporated for color tuning of the oligomers. Films of the materials were vacuum deposited on a Si/SiO₂ substrate. Devices made from the films were determined to work in the accumulation region as p-type transistors. Only a limited number of compounds were made, in which all of the fluorene units were unaltered in any way. However, Bao states that substituents on one or more rings can be added as desired.

U.S. Pat. No. 6,849,348 to Zheng et al. discloses organic compounds comprising complex fluorene structures represented by three different formulas that included fused aromatic or heteroaromatic rings. However, the compounds of Zheng et al. were mostly oligomers of relatively high weight average molecular weight, as shown in Table 1 of the patent. Zheng et al. disclosed that these compounds were highly efficient luminescent materials for use in organic electroluminescent devices. However, semiconductor properties for use in a transistor was not mentioned by Zheng et al.

It is the aim of the present invention to provide new materials, for use as semiconductors in transistors, having high charge mobility and good processability without adverse characteristics such as oxidative instability.

There is a need in the art for new and improved organic semiconductor materials for thin-film transistor devices and improved technology for their manufacture and use. There is especially a need for novel organic semiconductor materials exhibiting significant mobilities and high current on/off ratios.

### SUMMARY OF THE INVENTION

The present invention relates to the use of fused-fluorene-containing compounds in p-channel semiconductor films for thin film. Such films are capable of exhibiting field-effect electron mobility greater than 0.01 cm²/Vs in the film form. Such semiconductor films are also capable of providing device on/off ratios in the range of at least 10³.

Another aspect of the present invention is the use of such p-channel semiconductor films in thin film transistors, each such transistor further comprising spaced apart first and second contact means connected to a p-channel semiconductor film, and a third contact means spaced from said first and second contact means that is adapted for controlling, by means of a voltage applied to the third contact means, a current between the first and second contact means through said film. The first, second, and third contact means can correspond to a drain, source, and gate electrode in a field effect transistor. More specifically, an organic thin film transistor (OTFT) has an organic semiconductor layer. Any known thin film transistor construction option is possible with the invention. Another aspect of the present invention is directed to a process for fabricating a thin film transistor, preferably by sublimation or solution-phase deposition of the p-channel semiconductor film onto a substrate, wherein the substrate temperature is at a temperature of no more than 250° C., preferably no more than 200° C., more preferably no more than 150° C. during the deposition.

A fused-fluorene is a fluorene ring system to which at least one additional aromatic ring is fused, preferably a benzo aromatic ring. In one embodiment of the present invention, the organic materials comprise a fused-fluorene-containing material represented by one of the following Structures (I), (II), or (III):

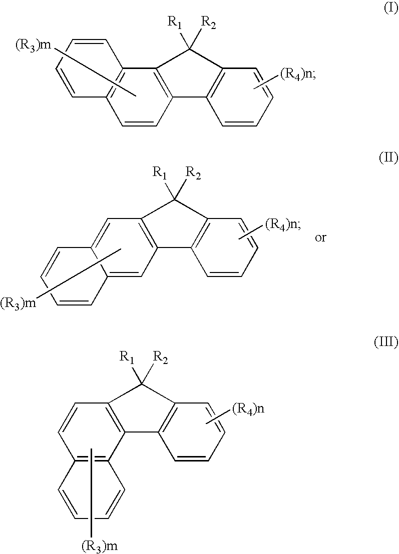

wherein:

R₁, R₂, R₃, and R₄ are optional substituents to replace corresponding ring hydrogens that are independently selected from the group consisting of hydroxy, thio, carboxy, sulfonyl, amino, alkyl, alkoxy of from 1 to 16 carbon atoms; aryl or substituted aryl of from 6 to 16 carbon atoms; heteroaryl or substituted heteroaryl of from 4 to 10 carbons; F, Cl, Br, cyano, and nitro groups; or any two adjacent R₃ substituents and/or any two adjacent R₄ substitutes can form a further aromatic ring fused to the corresponding aromatic ring in the above Structures; or R₁ and R₂ together form a cycloaliphatic ring having 3 to 6 carbons; and m is an integer from 0 to 6 and n is an integer from 0 to 4 (for example, when n is zero, the aromatic ring has four hydrogen atoms attached to four carbon ring atoms); or

wherein (when Structure I, II, or III is in an oligomer comprising multiple units selected from Structures I, II, and III and/or thiophene units), then in each of Structures I, II, and III, either an R₃ or an R₄ represents, or an R₃ and an R₄ each independently represents, instead of a substituent, the removal of a ring hydrogen to form, respectively, corresponding monovalent or divalent forms of Structures I, II, and III.

Thus, Structures I, II, and III can be monovalent, divalent, or zero-valence structures, as the case may be. The monovalent and divalent forms are part of oligomers comprising one or more additional units selected from monovalent or divalent Structures I, II, and III and/or one or more additional units of monovalent or divalent thiophene.

In preferred embodiments of oligomers, the monovalent or divalent forms of Structure I, II, or III above are serially bonded to either:

(i) one or more additional units selected from monovalent or divalent forms of Structures I, II, and III; or

(ii) one or more monovalent or divalent thiophene units; or

(iii) one or more additional units selected from monovalent or divalent forms of Structures I, II, and III and one or more substituted or unsubstituted monovalent or divalent thiophene units, in any order.

The fused-fluorene-containing Structures I, II, and III are each a compound or oligomer having a molecular weight of less than 2000 and comprising only 1 to 5 fused-fluorene-containing ring systems selected from Structure I, II, and III.

Preferably, the fused-fluorene-containing Structure I, II, and III, in the case of an oligomer, each comprises one or more of same structures selected from Structure I, II, or III, although mixed structures in the same oligomer are optional.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical or analogous features that are common to the figures, and wherein:

FIG. 1 illustrates a cross-sectional view of a typical organic thin film transistor having a bottom contact configuration;

FIG. 2 illustrates a cross-sectional view of a typical organic thin film transistor having a top contact configuration; and

FIGS. 3A and B are graphs illustrating the electrical performance of organic thin film transistors prepared according to Inventive Example 1.

### DESCRIPTION OF THE INVENTION

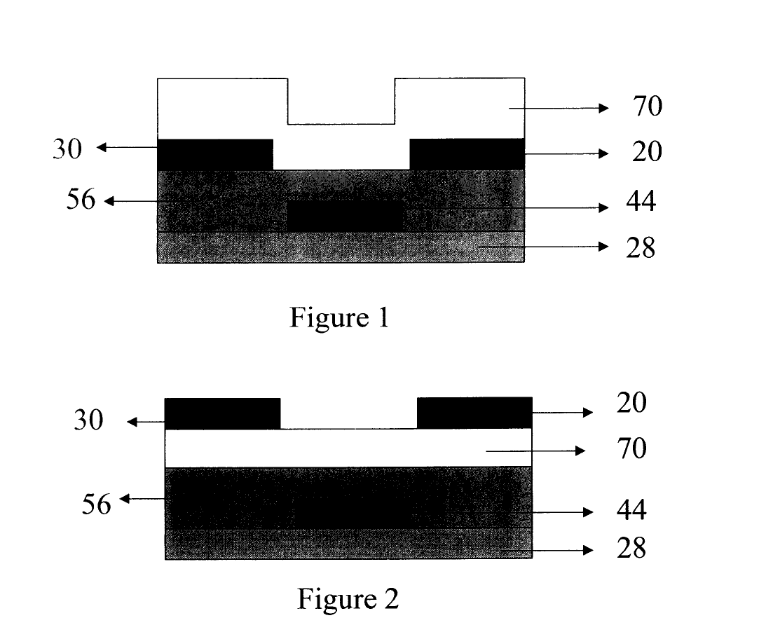

Cross-sectional views of typical organic thin film transistors are shown in FIGS. 1 and 2, wherein in FIG. 1 illustrates a typical bottom contact configuration and FIG. 2 illustrates a typical top contact configuration.

Each thin film transistor (TFT) in FIGS. 1 and 2 contains a source electrode 20, a drain electrode 30, a gate electrode 44, a gate dielectric 56, a substrate 28, and the semiconductor 70 of the invention in the form of a film connecting the source electrode 20 to drain electrode 30, which semiconductor comprises a compound selected from the class of fused-fluorene-containing materials described herein.

When the TFT operates in an accumulation mode, the charges injected from the source 20 into the semiconductor are mobile and a current flows from source to drain, mainly in a thin channel region within about 100 Angstroms of the semiconductor-dielectric interface. See A. a Dodabalapur, L. Torsi H. E. Katz, Science 1995, 268, 270, hereby incorporated by reference. In the configuration of FIG. 1, the charge need only be injected laterally from the source 20 to form the channel. In the absence of a gate field the channel ideally has few charge carriers; as a result there is ideally no source-drain conduction.

The off current is defined as the current flowing between the source electrode 20 and the drain electrode 30 when charge has not been intentionally injected into the channel by the application of a gate voltage. For an accumulation-mode TFT, this occurs for a gate-source voltage more positive, assuming a p-channel, than a certain voltage known as the threshold voltage. See Sze in Semiconductor Devices—Physics and Technology, John Wiley & Sons (1981), pages 438-443. The on current is defined as the current flowing between the source 20 and the drain 30 when charge carriers have been accumulated intentionally in the channel by application of an appropriate voltage to the gate electrode, and the channel is conducting. For a p-channel accumulation-mode TFT, this occurs at gate-source voltage more negative than the threshold voltage. It is desirable for this threshold voltage to be zero, or slightly negative, for p-channel operation. Switching between on and off is accomplished by the application and removal of an electric field from the gate electrode 44 across the gate dielectric 56 to the semiconductor-dielectric interface, effectively charging a capacitor.

The semiconductor film of the present invention, comprising the fused-fluorene-containing materials described herein, is capable of exhibiting field effect mobility greater than 0.001 cm²/Vs, preferably greater than 0.01 cm²/Vs. In addition, the p-channel semiconductor film of the invention is capable of providing on/off ratios of at least 10³, advantageously at least 10⁴. The on/off ratio is measured as the maximum/minimum of the drain current as the gate voltage is swept from zero to −60 volts and the drain-source voltage is held at a constant value of −50 volts, and employing a silicon dioxide gate dielectric.

The present invention provides novel semiconducting materials comprising a fused fluorene structure represented by formulae (I), (II), or (III), wherein R₁, R₂, R₃, and R₄ are optional substituents to replace hydrogen that are independently selected from the group consisting of hydroxy, thio, carboxy, sulfonyl, amino, alkyl, alkoxy of from 1 to 16 carbon atoms (preferably 1 to 6); aryl or substituted aryl of from 6 to 16 carbon atoms (preferably 6 to 14); heteroaryl or substituted heteroaryl of from 4 to 10 carbons; F, Cl, Br, cyano, and nitro groups; or any two adjacent substituents of R₃ and R₄ can form a further fused aromatic ring; or R₁ and R₂ together form a cycloaliphatic ring having 3 to 7 carbons (preferably 5 to 6); and is an integer from 0 to 6 and n is an integer from 0 to 4 (preferably, m and n preferably are each independently 0 to 4, more preferably 0 or 1 (for example, when n is zero, the aromatic ring has four hydrogen atoms attached to four carbon ring atoms); wherein, in each of Structures I, II, and III, either one of R₃ or one of R₄ represents, or one of R₃ and one of R₄ each independently represents, instead of a substituent, the removal of a ring hydrogen to form, respectively, corresponding monovalent or divalent forms of Structures I, II, and III.

Monovalent and Divalent forms of Structure I, II, and III can be serially bonded to either:

(i) one or more additional units selected from monovalent or divalent forms of Structures I, II, and III; or

(ii) one or more monovalent or divalent thiophene units; or

(iii) one or more additional units selected from monovalent or divalent forms of Structures I, II, and III and one or more substituted or unsubstituted monovalent or divalent thiophene units, in any order.

The fused-fluorene-containing Structures I, II, and III are each a compound or oligomer having a molecular weight of less than 2000, preferably less than 1000 (Examples are 380, 594, and 706) and comprising only 1 to 5 fused-fluorene-containing ring systems, that is a fluorene ring system to which at least one additional aromatic ring is fused. Preferably, the fused-fluorene-containing Structure I, II, and III, in the case of an oligomer, each comprises one or more of same structures selected from Structure I, II, or III, although mixed structures in the same oligomer are optional.

Furthermore, when an R₃ and R₄ represent the removal of a ring hydrogen to form corresponding monovalent or divalent forms, they are preferably positioned at the most terminal position of the structure along the axis of the bond joining the separated aromatic ring systems in the Structures I, II, and III.

Each of said monovalent or divalent thiophene units, if present, in the fused-fluorene-containing material of Structure I, II, and III is represented, respectively, by the following Structure IV:

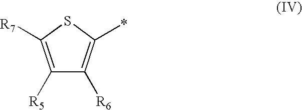

wherein each R₅, R₆, and R₇, if present, is independently hydrogen or any of the substituents mentioned for R₃ and R₄, or R₇ represents, instead of hydrogen or a substituent, the removal of a ring hydrogen to form a corresponding divalent form. Preferably, if present, each R₅ and each R₆ in Structure I, II, and III is independently the same group.

Thus, in one class of compounds, a monovalent or divalent form of Structure I, II, or III can be connected to one or more additional units selected from monovalent or divalent Structure I, II, and III, optionally through one or more substituted or unsubstituted monovalent or divalent thiophene units.

For example, R₁, R₂, R₃, and R₄ independently can be methyl, ethyl, propyl, isopropyl, butyl, isobutyl, t-butyl, pentyl, hexyl, ethylhexyl, heptyl, octyl, nonyl, decyl, dodecyl, hexyadecyl, cyclohexyl, cyclopentyl, methoxy, ethoxy, butoxy, hexyloxy, ethylhexyloxy, methoxyethoxyethyl, methoxyethyloxyethoxyethyl, phenyl, alkyl phenyl, tolyl, nathphyl, xylene, anthracene, thiophene, phenanthrene, phenylmethylenephenyl, benzyl, phenoxy, pyridyl, thiophenyl; or R₁ and R₂ together form a cyclic ring such as cyclopentyl, cyclohexyl, tetralonyl, or fluorenyl; adjacent R₃ groups and/or adjacent R₄ groups can form fused aromatic or heteroaromatic rings combining to form, for example, a naphthalene, anthracene, perylene, phenanthrene, pyrene, tetracene, pentacene, triphenylene, and benzo[a]pyrene ring system. Preferred R₁, R₂, R₃, and R₄ substituents are t-butyl, hexyl, 2-ethylhexyl, octyl, 3,7-dimethyloctyl, decyl, heptyl, phenyl, 2-ethylhexyloxy, or 4-methoxypheny; R₁ and R₂ together form a cyclohexyl, cyclopentyl, fluorenyl; or R₁ and R₂ together form methylene, dicyanomethylene, cyclohexylene, and cyclopentylene; adjacent R₃ groups form fused aromatic rings combining to form an anthracene, or perylene, or pyrene, phenanthrene, or tetracene ring system; and adjacent R₄ groups form fused aromatic rings combining to form a naphthalene or anthracene ring system.

The organic materials comprising the fused-fluorene-structures of the present invention are small molecules or oligomers, and can be used in a combination of two or more thereof.

A preferred class of oligomers according to the present invention comprises small molecules comprising the fused-fluorene-containing material are represented by formula (V):

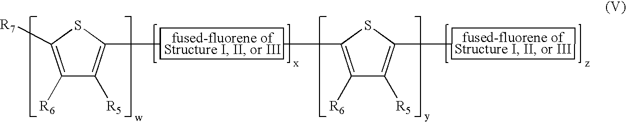

wherein each R₅, R₆, and R₇ is as defined above, that is, independently hydrogen or any of the substituents mentioned for R₃ and R₄. The fused-fluorine structures in structure (V) can be monovalent, divalent, or zero-valence as the case may be.

In Structure V above, w is 0 to 5, preferably 0, 1, 2, or 3; x is 0 to 3, preferably 1 or 2, y is 0 to 5, preferably 0, 1, 2, or 3; z is 0 to 2, preferably 0, 1, or 2, so long as x and z are not both zero. Thus, when w, y, and z are zero, Structure V becomes a zero-valence compound according to Structure I, II, or III.

Structure V represents a preferred class of oligomers when at least two of w, x, y, and z are not zero.

The substituents on R₅ and R₆ wherein R₅ and R₆ are optional substituents to replace hydrogen that are independently selected from the group consisting of hydroxy, thio, carboxy, sulfonyl, amino, alkyl, alkoxy of from 1 to 6 carbon atoms; alkylaryl, aryl or substituted aryl of from 6 to 14; heteroaryl or substituted heteroaryl of from 4 to 10 carbons; and F, Cl, Br, cyano, and nitro groups. The fused-fluorene structure (IV) a compound or oligomer having a molecular weight of less than 2000 and comprises 1 to 5 fused-fluorene units of Structure I, II, or III.

Preferably, the fused-fluorene compound used in the present invention comprises, if the material only has one fused-fluorene unit, also comprises at least one, preferably at least two, additional aromatic or heteroaromatic ring structures. More preferably, the additional aromatic or heteroaromatic ring structures are fully conjugated. If the material comprises two fused-fluorene units connected end to end either directly, i.e. a single bond, or through one or more intermediate ring units that is not a fused fluorene, then preferably the two fused-fluorene units and the intermediate units are preferably fully conjugated.

The compounds of the above structure can be prepared as described in the Examples below and as taught by U.S. Pat. No. 6,849,348 to Zheng et al., hereby incorporated by reference in its entirety.

Organic compounds and oligomers comprising fused-fluorene Structures (I), (II) or (III) can be synthesized using known methods. And they may be prepared by aryl-aryl coupling reactions such as Pd-catalyzed Suzuki coupling, Stille coupling or Heck coupling, or Ni-mediated Yamamoto coupling, or by other condensation reactions such as Wittig reaction, or Horner-Emmons reaction, or Knoevenagel reaction.

Suzuki coupling reaction was first reported by Suzuki et al on the coupling of aromatic boronic acid derivatives with aromatic halides (Suzuki, A. et al Synthetic Comm. 1981, 11(7), 513). The reaction involves the use of a palladium-based catalyst such as a soluble Pd compound either in the state of Pd (II) or Pd (O), a base such as an aqueous inorganic alkaline carbonate or bicarbonate, and a solvent for the reactants and/or product. The preferred Pd catalyst is a Pd (O) complex such as Pd(PPh₃)₄ or a Pd (II) salt such as Pd(PPh₃)₂Cl₂ or Pd(OAc)₂ with a tertiary phosphine ligand, and used in the range of 0.01-10 mol % based on the functional groups of the reactants. A variation of the Suzuki coupling reaction replaces the aromatic halide with an aromatic trifluoromethanesulfonate (triflate) (Ritter, K. Synthesis, 1993, 735). Aromatic triflates are readily prepared from the corresponding phenol derivatives. The advantages of using aromatic triflates are that the phenol derivatives are easily accessible and can be protected/deprotected during complex synthesis. For example, aromatic halides normally would react under various coupling conditions to generate unwanted by-product and lead to much more complicated synthetic schemes. However, phenol derivatives can be easily protected by various protecting groups which would not interfere with functional group transformation and be deprotected to generate back the phenol group which then can be converted to triflates. The diboron derivatives can be prepared from the corresponding dihalide or ditriflate.

The following molecular structures constitute specific examples of preferred compounds satisfying the requirement of this invention:

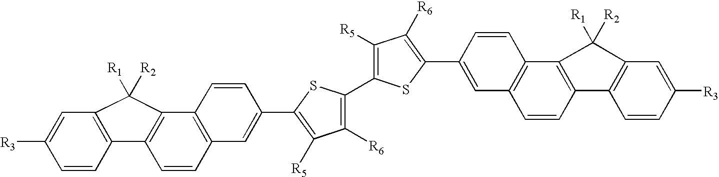

Compound 1 R₁=R₂=methyl, R₅=R₆=R₃=H

Compound 2 R₁=R₂=R₅=R₆=R₇=H

Compound 3 R₁=R₂=R₅=methyl, R₆=R₃=H

Compound 4 R₁=R₂=ethyl, R₅=R₆=R₃=H

Compound 5 R₁=R₂=n-hexyl, R₅=methyl, R₆=R₇=H

Compound 6 R₁=R₂=R₃=methyl, R₅=R₆=H

Compound 7 R₁=R₂=R₃=R₅=R₆=methyl

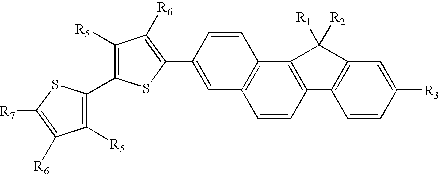

Compound 8 R₁=R₂=methyl, R₅=R₆=R₇=R₃=H

Compound 9 R₁=R₂=R₅=R₆=R₇=R₃=H

Compound 10 R₁=R₂=R₅=methyl, R₆=R₇=R₃=H

Compound 11 R₁=R₂=ethyl, R₅=R₆=R₇=H, R₃=n-hexyl

Compound 12 R₁=R₂=R₃=n-hexyl, R₅=R₇=R₆=H

Compound 13 R₁=R₂=R₇=R₃=methyl, R₅=R₆=H

Compound 14 R₁=R₂=R₅=R₆=R₇=R₃=methyl

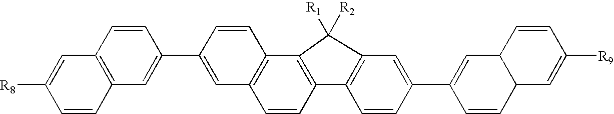

Compound 15 R₁=R₂=methyl, R₉=R₈=H

Compound 16 R₁=R₂=R₉=R₈=methyl

Compound 17 R₁=R₂=n-hexyl, R₉=R₈=phenyl

Compound 18 R₁=R₂=ethyl, R₉=R₈=n-hexyl

Compound 19 R₁=R₂=R₈=n-hexyl, R₉=H

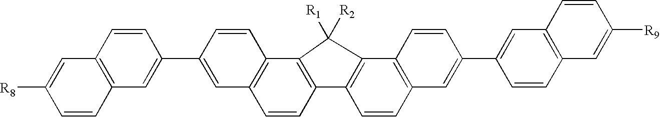

Compound 20 R₁=R₂=methyl, R₉=R₈=H

Compound 21 R₁=R₂=R₉=R₈=methyl

Compound 22 R₁=R₂=n-hexyl, R₇=R₈=phenyl

Compound 23 R₁=R₂=ethyl, R₉=R₈=n-hexyl

Compound 24 R₁=R₂=R₈=n-hexyl, R₉=phenyl

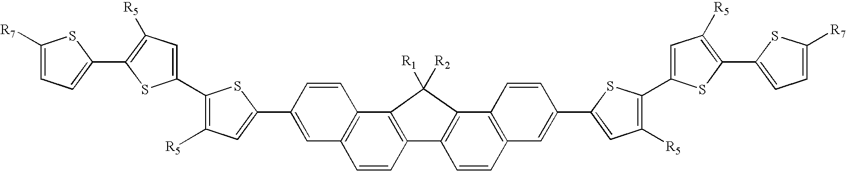

Compound 25 R₁=R₂=R₇=R₅=ethyl

Compound 26 R₁=R₂=R₇=R₅=n-hexyl

Compound 27 R₁=R₇=n-hexyl, R₂=2-ethylhexyl, R₅=H

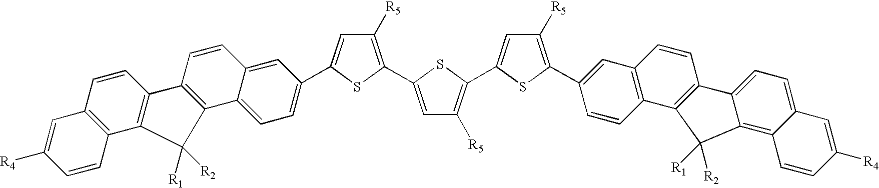

Compound 28 R₁=R₂=R₄=R₅=ethyl

Compound 29 R₁=R₂=R₄=R₅=n-hexyl

compound 30 R₁=R₄=n-hexyl, R₂=2-ethylhexyl, R₅=H

Compound 31 R₁=R₂=R₅=ethyl, R₄=phenyl

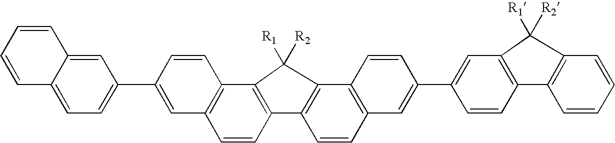

Compound 32 R₁=R₂=n-hexyl, R_{1′}=R₂=2′-ethylhexyl

Compound 33 R₁=R_{1′}=ethyl, R₂=R_{2′}=hexyl

Compound 34 R₁=R₂=R_{1′}=R₂=4-methyllphenyl

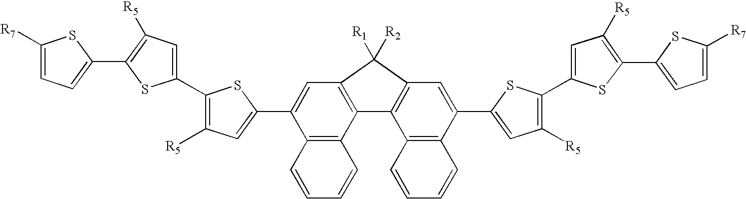

Compound 35 R₁=R₂=R₇, R₅=n-hexyl

Compound 36 R₁=R₂=R₅=n-hexyl, R₇=phenyl

Compound 37 R₁=R₂=R₅=n-hexyl, R₇=4-methylphenyl

Compound 38 R₁=R₂=4-methylphenyl, R₇=n-hexyl, R₅=H

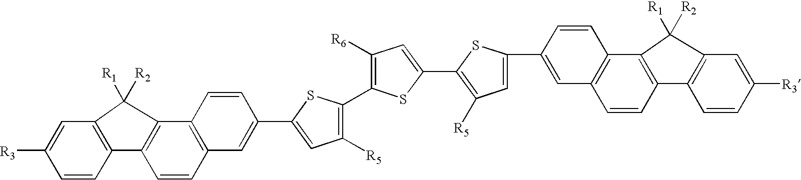

Compound 39 R₁=R₂=ethyl, R₇=R_{3′}=R₉=R₆=H

Compound 40 R₁=R₂=R₇=R_{3′}=phenyl, R₅=R₆=H

Compound 41 R₁=R₂=n-hexyl, R₇=R_{3′}=phenyl, R₅=R₆=ethyl

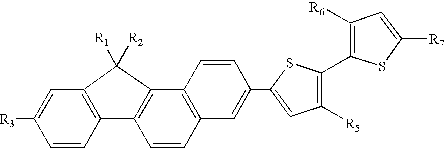

Compound 42 R₁=R₂=R₃=R₇=n-hexyl, R₉=R₆=H

Compound 43 R₁=R₂=ethyl, R₃=R₇=phenyl, R₅=R₆=n-hexyl

Compound 44 R₁=R₂=phenyl, R₃=R₇=n-hexyl, R₅=R₆=H

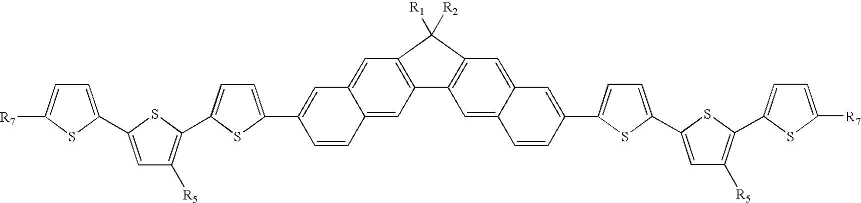

Compound 45 R₁=R₇=R₂=R₅=ethyl

Compound 46 R₁=R₂=H, R₇=methyl, R₅=n-hexyl

Compound 47 R₁=R₂=R₇=phenyl, R₅=n-hexyl

The present invention is not limited to the specific molecular structures shown above. Any compounds and oligomers, or mixtures thereof, which is consistent with general Structure I, II, or III can be used.

Another aspect of the present invention relates to a process for the production of thin film semiconductor devices. In one embodiment, a substrate is provided and a layer of the semiconductor material as described above can be applied to the substrate, electrical contacts being made with the layer. The exact process sequence is determined by the structure of the desired semiconductor component. Thus, in the production of an organic field effect transistor, for example, a gate electrode can be first deposited on a flexible substrate, for example an organic polymer film, the gate electrode can then be insulated with a dielectric and then source and drain electrodes and a layer of the n-channel semiconductor material can be applied on top. The structure of such a transistor and hence the sequence of its production can be varied in the customary manner known to a person skilled in the art. Thus, alternatively, a gate electrode can be deposited first, followed by a gate dielectric, then the organic semiconductor can be applied, and finally the contacts for the source electrode and drain electrode deposited on the semiconductor layer. A third structure could have the source and drain electrodes deposited first, then the organic semiconductor, with dielectric and gate electrode deposited on top.

In yet another embodiment of the present invention, source drain and gate can all be on a common substrate and the gate dielectric can enclose gate electrode such that gate electrode is electrically insulated from source electrode and drain electrode, and the semiconductor layer can be positioned over the source, drain and dielectric.

The skilled artisan will recognize other structures can be constructed and/or intermediate surface modifying layers can be interposed between the above-described components of the thin film transistor.

A support can be used for supporting the OTFT during manufacturing, testing, and/or use. The skilled artisan will appreciate that a support selected for commercial embodiments may be different from one selected for testing or screening various embodiments. In some embodiments, the support does not provide any necessary electrical function for the TFT. This type of support is termed a “non-participating support” in this document. Useful materials can include organic or inorganic materials. For example, the support may comprise inorganic glasses, ceramic foils, polymeric materials, filled polymeric materials, coated metallic foils, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(phenylene sulfide) (PPS), and fiber-reinforced plastics (FRP).

A flexible support is used in some embodiments of the present invention. This allows for roll processing, which may be continuous, providing economy of scale and economy of manufacturing over flat and/or rigid supports. The flexible support chosen preferably is capable of wrapping around the circumference of a cylinder of less than about 50 cm diameter, more preferably 25 cm diameter, most preferably 10 cm diameter, without distorting or breaking, using low force as by unaided hands. The preferred flexible support may be rolled upon itself.

In some embodiments of the invention, the support is optional. For example, in a top construction as in FIG. 2, when the gate electrode and/or gate dielectric provides sufficient support for the intended use of the resultant TFT, the support is not required.

In addition, the support may be combined with a temporary support. In such an embodiment, a support may be detachably adhered or mechanically affixed to the support, such as when the support is desired for a temporary purpose, e.g., manufacturing, transport, testing, and/or storage. For example, a flexible polymeric support may be adhered to a rigid glass support, which support could be removed.

The gate electrode can be any useful conductive material. A variety of gate materials known in the art, are also suitable, including metals, degenerately doped semiconductors, conducting polymers, and printable materials such as carbon ink or silver-epoxy. For example, the gate electrode may comprise doped silicon, or a metal, such as aluminum, chromium, gold, silver, nickel, palladium, platinum, tantalum, and titanium. Conductive polymers also can be used, for example polyaniline, poly(3,4-ethylenedioxythiophene)/poly(styrene sulfonate) (PEDOT:PSS). In addition, alloys, combinations, and multilayers of these materials may be useful.

In some embodiments of the invention, the same material can provide the gate electrode function and also provide the support function of the support. For example, doped silicon can function as the gate electrode and support the OTFT.

The gate dielectric is provided on the gate electrode. This gate dielectric electrically insulates the gate electrode from the balance of the OTFT device. Thus, the gate dielectric comprises an electrically insulating material. The gate dielectric should have a dielectric constant above about 2, more preferably above about 5. The dielectric constant of the gate dielectric also can be very high if desired, for example, 80 to 100 or even higher. Useful materials for the gate dielectric may comprise, for example, an inorganic electrically insulating material. The gate dielectric may comprise a polymeric material, such as polyvinylidenedifluoride (PVDF), cyanocelluloses, polyimides, etc.

Specific examples of materials useful for the gate dielectric include strontiates, tantalates, titanates, zirconates, aluminum oxides, silicon oxides, tantalum oxides, titanium oxides, silicon nitrides, barium titanate, barium strontium titanate, barium zirconate titanate, zinc selenide, and zinc sulfide. In addition, alloys, combinations, and multilayers of these examples can be used for the gate dielectric. Of these materials, aluminum oxides, silicon oxides, and zinc selenide are preferred. In addition, polymeric materials such as polyimides, and insulators that exhibit a high dielectric constant. Such insulators are discussed in U.S. Pat. No. 5,981,970 hereby incorporated by reference.

The gate dielectric can be provided in the OTFT as a separate layer, or formed on the gate such as by oxidizing the gate material to form the gate dielectric. The dielectric layer may comprise two or more layers having different dielectric constants.

The source electrode and drain electrode are separated from the gate electrode by the gate dielectric, while the organic semiconductor layer can be over or under the source electrode and drain electrode. The source and drain electrodes can be any useful conductive material. Useful materials include most of those materials described above for the gate electrode, for example, aluminum, barium, calcium, chromium, gold, silver, nickel, palladium, platinum, titanium, polyaniline, PEDOT:PSS, other conducting polymers, alloys thereof, combinations thereof, and multilayers thereof.

The thin film electrodes (e.g., gate electrode, source electrode, and drain electrode) can be provided by any useful means such as physical vapor deposition (e.g., thermal evaporation, sputtering) or ink jet printing. The patterning of these electrodes can be accomplished by known methods such as shadow masking, additive photolithography, subtractive photolithography, printing, microcontact printing, and pattern coating.

The organic semiconductor layer can be provided over or under the source and drain electrodes, as described above in reference to the thin film transistor article. The present invention also provides an integrated circuit comprising a plurality of OTFTs made by the process described herein. The semiconductor material made using the above fused-fluorene-containing materials are capable of being formed on any suitable substrate which can comprise the support and any intermediate layers such as a dielectric or insulator material, including those known in the art.

The entire process of making the thin film transistor or integrated circuit of the present invention can be carried out below a maximum support temperature of about 450° C., preferably below about 250° C., more preferably below about 150° C., and even more preferably below about 100° C., or even at temperatures around room temperature (about 25° C. to 70° C.). The temperature selection generally depends on the support and processing parameters known in the art, once one is armed with the knowledge of the present invention contained herein. These temperatures are well below traditional integrated circuit and semiconductor processing temperatures, which enables the use of any of a variety of relatively inexpensive supports, such as flexible polymeric supports. Thus, the invention enables production of relatively inexpensive integrated circuits containing organic thin film transistors with significantly improved performance.

Compounds used in the invention can be readily processed and are thermally stable to such an extent that they can be vaporized. The compounds possess significant volatility, so that vapor phase deposition, where desired, is readily achieved. Such compounds can be deposited onto substrates by vacuum sublimation or by solvent processing, including dip coating, drop casting, spin coating, blade coating.

Deposition by a rapid sublimation method is also possible. One such method is to apply a vacuum of 35 mtorr to a chamber containing a substrate and a source vessel that holds the compound in powdered form, and heat the vessel over several minutes until the compound sublimes onto the substrate. Generally, the most useful compounds form well-ordered films, with amorphous films being less useful.

Alternatively, for example, the compounds described above can first be dissolved in a solvent prior to spin-coating or printing for deposition on a substrate.

Devices in which the p-channel semiconductor films of the invention are useful include especially thin film transistors (TFTs), especially organic field effect thin-film transistors. Also, such films can be used in various types of devices having organic p-n junctions, such as described on pages 13 to 15 of US 2004/0021204 A1 to Liu et al., which patent application publication is hereby incorporated by reference.

Electronic devices in which TFTs and other devices are useful include, for example, more complex circuits, e.g., shift registers, integrated circuits, logic circuits, smart cards, memory devices, radio-frequency identification tags, backplanes for active matrix displays, active-matrix displays (e.g. liquid crystal or OLED), solar cells, ring oscillators, and complementary circuits, such as inverter circuits, for example, in combination with other transistors made using available p-type organic semiconductor materials such as pentacene. In an active matrix display, a transistor according to the present invention can be used as part of voltage hold circuitry of a pixel of the display.

In devices containing the TFTs of the present invention, such TFTs are operatively connected by means known in the art.

The present invention further provides a method of making any of the electronic devices described above. Thus, the present invention can be embodied in an article that comprises one or more of the TFTs described.

### EXAMPLES

### A. Material Synthesis

In accordance with the invention, a typical synthesis of fused-fluorene-containing compounds used in the present invention is illustrated in Schemes 1 and 2 below.

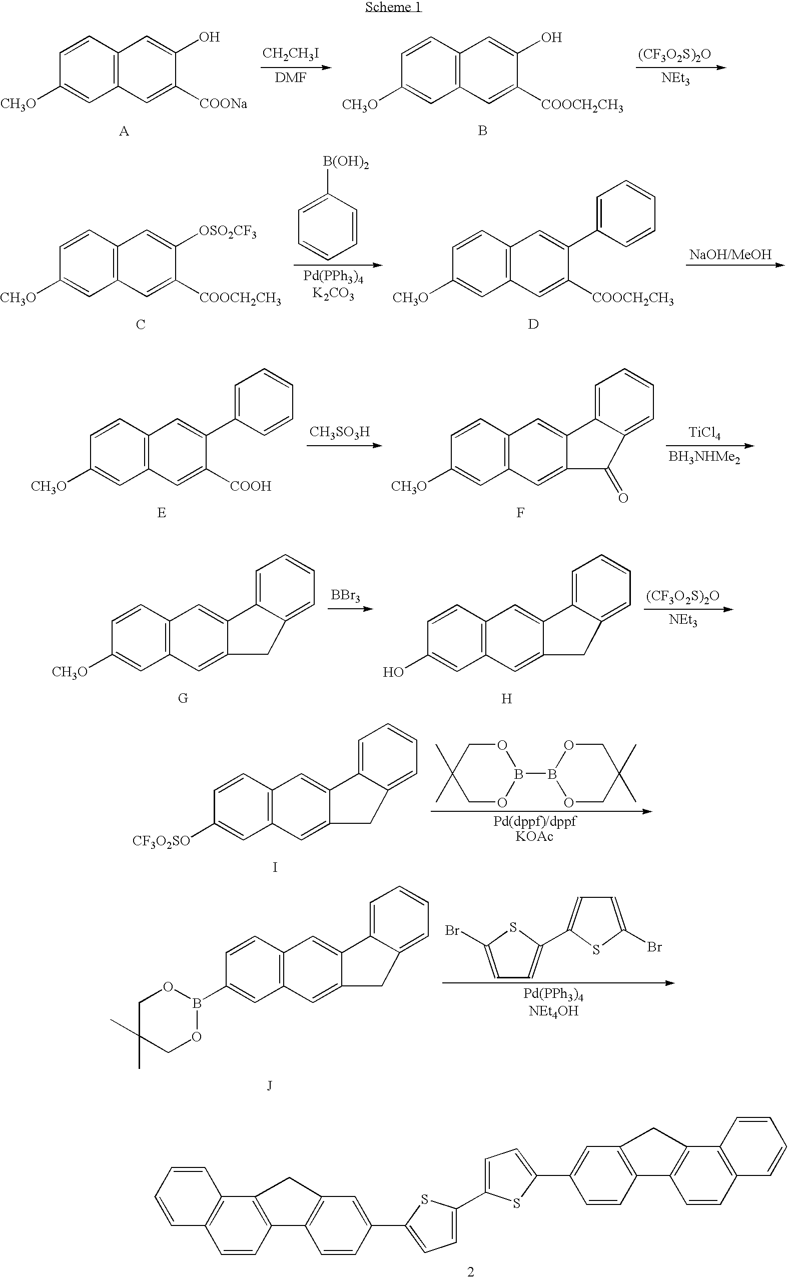

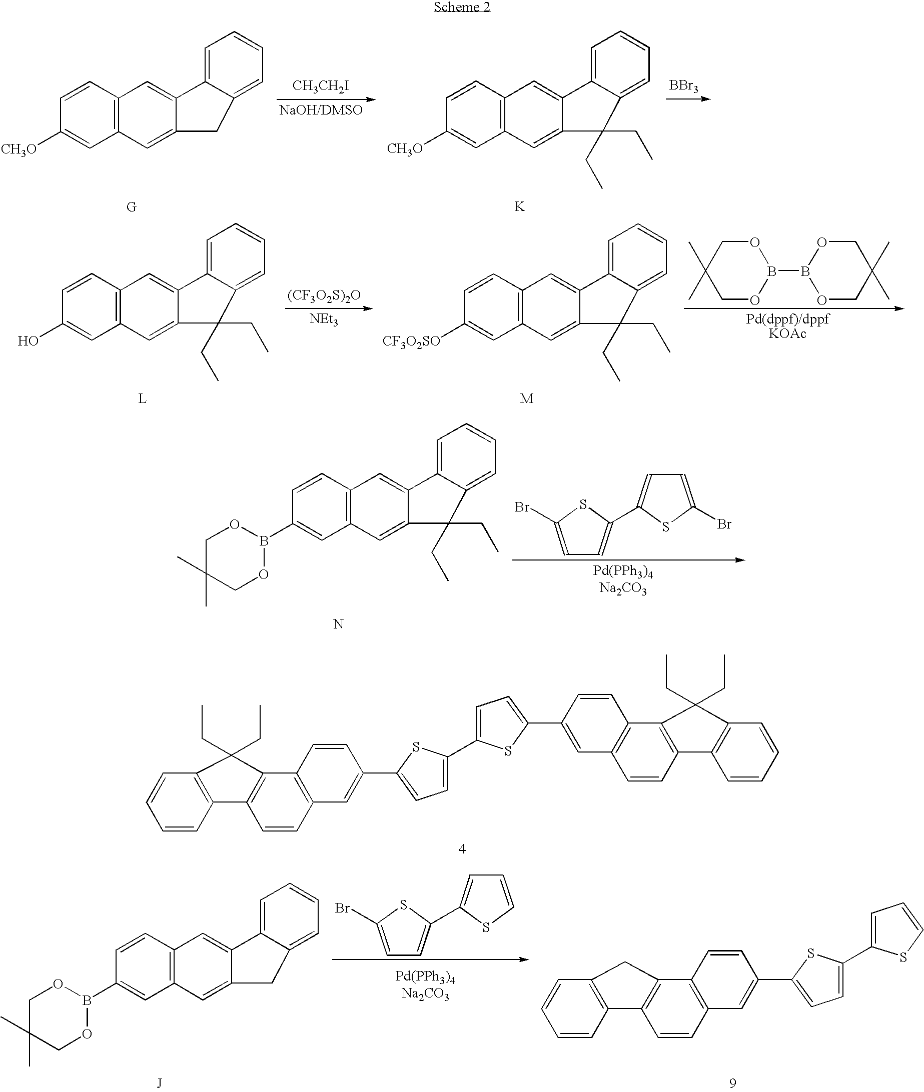

### SYNTHETIC EXAMPLES

### Example 1

### Synthesis of Compound B

Compound A (Fluka) (100 g, 0.42 mol) was dissolved in 500 mL of DMF and ethyliodide (71.4 g, 0.46 mol) was added dropwise. The reaction was heated to 90° C.

The reaction became clear and tuned to dark yellow. After 1 hour, the reaction was 1 (cooled down and the product was precipitated from water. The crude product was recrystallized from heptane to give 85 g of pure product as yellow needle (84% yield). FD-MS: 246 (M⁺).

### Example 2

### Synthesis of Compound C

Compound B (60.0 g, 0.24 mol) was dissolved in 300 mL of methylene chloride and cooled to 0° C. To the solution was added triethylamine (27.1 g, 0.27 mol), followed by slow addition of triflate anhydride (75.7 g, 0.27 mol). The mixture was stirred at room temperature overnight until the completion of the reaction. The reaction was quenched with water, extracted with methylene chloride and dried over MgSO₄. The crude product was recrystallized from ethanol to give 82 g pure product as yellow solid (89% yield). FD-MS: 378 (M⁺).

### Example 3

### Synthesis of Compound D

Compound C (10 g, 0.026 mol) and phenyl boronic acid (3.5 g, 0.029 mol) were dissolved in 100 mL of toluene and 2 M solution of K₂CO₃ (46 mL, 0.092 mol) and a few drops of phase transfer reagent Aquat 336 were added. The mixture was bubbled with nitrogen for 20 minutes and catalyst tetrakis(triphenylphosphine) palladium (0.45 g, 1.5 mol %) was added. The reaction was heated to 100° C. for 1 hour and cooled down. The organic phase was separated and the aqueous phase was extracted with methylene chloride. The combined organic phase was dried over MgSO₄. The crude product was passed through a pad of silica gel and recrystallized from ethanol to give 7.3 g of pure product as creamy flaky crystal (90% yield). FD-MS: 306 (M⁺).

### Example 4

### Synthesis of Compound E

Compound D (7.1 g, 0.020 mol) was dissolved in 30 mL of DMSO and sodium hydroxide solution (50% in water, 10 mL) was added. The reaction was heated to 100° C. for 30 minutes and cooled down. Concentrated HCl solution was added to adjust pH to 1. White precipitate formed and was collected by filtration. It was then dissolved in ethyl acetate and dried over MgSO₄. Solvent was removed to give 5.8 g of product as creamy solid (89% yield). FD-MS: 278 (M⁺).

### Example 5

### Synthesis of Compound F

Compound E (11 g, 0.040 mol) was dissolved in 30 mL of methanesulfonic acid and heated to 60° C. for 30 minutes and cooled down. The product was precipitated from water to give yellow solid and recrystallized from toluene to give 9 g of pure product as yellow fluffy crystals (87% yield). FD-MS: 260 (M⁺).

### Example 6

### Synthesis of Compound G

Compound F (6.5 g, 0.025 mol) was dissolved in 60 mL of methylene chloride and borane-dimethylamine (3.6 g, 0.063 mol) was added. The reaction was cooled to 0° C. and titanium tetrachloride (1 M solution in methylene chloride, 62.5 mL) was added dropwise. After 10 minutes, the reaction was quenched with saturated sodium carbonate solution and extracted with methylene chloride. The combined organic phase was dried over MgSO₄. The crude product was purified by column chromatography using heptane as an eluent and then recrystallized from heptane to give 4.8 g of pure product as white solid (79% yield). FD-MS: 246 (M⁺).

### Example 7

### Synthesis of Compound H

Compound G (1.7 g, 7 mmol) was dissolved in 20 mL of methylene chloride 0.5 and was cooled to 0° C. To this solution was added boron tribromide (1 M solution in methylene chloride, 17 mL, 17 mmol) dropwise. After 1 hour, the reaction was quenched with saturated sodium bicarbonate. The aqueous layer was extracted with ethyl acetate and the combined organic layer was washed with water and dried over MgSO₄. The crude product was purified by column chromatography using 15/85 (v/v) ether/heptane as an eluent to give 1.2 g of pure product as off-white solid (75% yield). FD-MS: 246 (M⁺).

### Example 8

### Synthesis of Compound I

Compound H (1.2 g, 5.2 mmol) was dissolved in 20 mL of methylene chloride and cooled to 0° C. To the suspension was added triethylamine (0.58 g, 5.7 mmol). The reaction turned clear and triflate anhydride (1.6 g, 5.7 mmol) was added. After 30 minutes, the reaction was quenched with water, extracted with methylene chloride and dried over MgSO₄. The crude product was recrystallized from ethanol to give 0.8 g pure product as light brown solid (43% yield). FD-MS: 364 (M⁺).

### Example 9

### Synthesis of Compound J

Compound I (3.1 g, 8.5 mmol), bis(neopentyl glycol)diboron (2 g, 9.4 mmol) and potassium acetate (2.4 g, 24 mmol) were mixed in 30 mL of dioxane. The mixture was bubbled with nitrogen for 10 min and catalyst bis(diphenylphosphino)ferrocene palladium chloride (Pd(dppf)₂Cl₂) (140 mg, 0.02 mol %) and ligand dppf (94 mg, 0.02 mol %) were added. The reaction was heated at 80° C. under nitrogen for 1 hour and cooled down. The reaction was extracted with methylene chloride and water, and the crude product was passed through a short column of silica using 30/70 (v/v) methylene chloride/heptane as an eluent and then recrystallized from heptane to give 2.2 g of pure product as off-white solid (78% yield). FD-MS: 328 (M⁺).

### Example 10

### Synthesis of Compound 2

Compound J (2.2 g, 6.7 mmol) and bithiophene dibromide (1.0 g, 3.1 mmol) were dissolved in 30 mL of toluene. To this solution was added tetraethylammonium hydroxide (20 wt % in water, 6.6 mL, 9.3 mmol). The mixture was bubbled with nitrogen for 10 minutes and catalyst Pd(PPh₃)₄ (0.10 g, 2 mol %) was added. The reaction was heated to 105° C. for 3 hours and cooled down. The product was not very soluble and precipitated out of reaction. The crude product 0.9 g was filtered off and purified by sublimation at 350° C. to give light orange crystals. FD-MS: 594 (M⁺).

### Example 11

### Synthesis of Compound K

Compound J (5.5 g, 0.022 mol) was suspended in 16 mL of DMSO and the mixture was degassed by bubbling with nitrogen for 10 min. To this mixture was added 3 drops of phase transfer reagent AQUAT 336 and 50% NaOH aqueous solution (3.5 g, 0.044 mol) under nitrogen. The reaction turned bright orange immediately. Ethyliodide (8.6 g, 0.055 mol) was then added dropwise and the reaction was heated to 80° C. The orange color disappeared and reaction became light yellow and clear. After 20 minutes, the reaction was poured into water and extracted with ether. The combined organic phase was washed with water and dried over MgSO₄. The crude product was purified by column chromatography using heptane as an eluent to give 5.1 g pure product as light yellow solid (77% yield). FD-MS: 302 (M⁺).

### Example 12

### Synthesis of Compound L

Compound K (5.0 g, 0.0165 mol) was dissolved in 20 mL of methylene chloride and was cooled to 0° C. To this solution was added boron tribromide (1 M solution in methylene chloride, 33 mL, 0.033 mol) dropwise. After 30 minutes, the reaction was quenched with saturated sodium bicarbonate. The aqueous layer was extracted with ethyl acetate and the combined organic layer was washed with water and dried over MgSO₄. The crude product was purified by column chromatography using 15/85 (v/v) ether/heptane as an eluent g to give 3.9 g of pure product as off-white solid (83% yield). FD-MS: 288 (M⁺).

### Example 13

### Synthesis of Compound M

Compound L (3.8 g, 0.013 mol) was dissolved in 20 mL of methylene chloride and cooled to 0° C. To the suspension was added triethylamine (2.7 g, 0.026 mol). The reaction turned clear and triflate anhydride (7.4 g, 0.026 mol) was added. After 35 minutes, the reaction was quenched with water, extracted with methylene chloride and dried over MgSO₄. The crude product was purified by column chromatography using 20/80 (v/v) ether/heptane as an eluent g to give 4.4 g of pure product as light yellow viscous oil (79% yield). FD-MS: 420 (M⁺).

### Example 14

### Synthesis of Compound N

Compound M (4.3 g, 0.10 mol), bis(neopentyl glycol)diboron (2.5 g, 0.011 mol) and potassium acetate (3.0 g, 0.031 mol) were mixed in 50 mL of dioxane. The mixture was bubbled with nitrogen for 10 minutes and catalyst bis(diphenylphosphino)ferrocene palladium chloride (Pd(dppf)₂Cl₂) (163 mg, 0.02 mol %) and ligand dppf (111 mg, 0.02 mol %) were added. The reaction was heated at 80° C. under nitrogen for 2 hours and cooled down. The reaction was extracted with methylene chloride and water, and the crude product was purified by column chromatography using 25/75 (v/v) ether/heptane as an eluent and to give 2.9 g of pure product as off-white solid (75% yield). FD-MS: 384 (M⁺).

### Example 15

### Synthesis of Compound 4

Compound N (2.9 g, 7.5 mmol) and bithiophene dibromide (1.2 g, 3.5 mmol) were dissolved in 30 mL of toluene. To this solution was added 2 M solution of Na₂CO₃ (5.3 mL, 10.6 mmol) and a few drops of phase transfer reagent Aquat 336. The mixture was bubbled with nitrogen for 20 minutes and catalyst tetrakis(triphenylphosphine) palladium (0.17 g, 2 mol %) was added. The reaction was heated to 105° C. for 1 hour and cooled down. The product was not very soluble and precipitated out of reaction. The crude product 1.9 g was filtered off and purified by sublimation at 350° C. to give light orange crystals. FD-MS: 706 (M⁺).

### Example 16

### Synthesis of Compound 9

Compound J (0.9 g, 2.9 mmol) and bithiophene monobromide (0.78 g, 3.2 mmol) were dissolved in 30 mL of toluene. To this solution was added 2 M solution of Na₂CO₃ (2.9 mL, 5.8 mmol) and a few drops of phase transfer reagent Aquat 336. The mixture was bubbled with nitrogen for 20 minutes and catalyst tetrakis(triphenylphosphine) palladium (67 mg, 2 mol %) was added. The reaction was heated to 105° C. for 1 hour and cooled down. The product was not very soluble and precipitated out of reaction. The crude product 0.7 g was filtered off and purified by sublimation at 300° C. to give light orange crystals. FD-MS: 380 (M⁺).

B. Device Preparation

In order to test the electrical characteristics of the various materials of this invention, field-effect transistors were typically made using the top-contact geometry.

The substrate used is a heavily doped silicon wafer, which also serves as the gate of the transistor. The gate dielectric is a thermally grown SiO₂ layer with a thickness of 165 nm. It has been previously shown for both p-type and n-type transistors that electrical properties can be improved by treating the surface of the gate dielectric. For most of the experiments described here, the oxide surface was treated with a thin (<10 nm), spin-coated polymer layer, or a self-assembled monolayer (SAM) of octadecyltrichlorosilane (OTS). Typically, an untreated oxide sample was included in the experiments for comparison.

The active layer of fused-fluorene-containing material was deposited via vacuum deposition in a thermal evaporator. The deposition rate was 0.5 Angstroms per second while the substrate temperature was held at 50° C. for most experiments. The thickness of the active layer was a variable in some experiments, but was typically 40 nm. Gold contacts of thickness 50 nm were deposited through a shadow mask. The channel width was held at 500 microns, while the channel lengths were varied between 20 and 80 microns. Some experiments were performed to look at the effect of other contact materials.

C. Device Measurement and Analysis

Electrical characterization of the fabricated devices was performed with a Hewlett Packard HP 4145b parameter analyzer. Samples were stored in vacuum, but all measurements were performed under ambient conditions.

For each experiment performed, between 4 and 10 individual devices were tested on each sample prepared, and the results were averaged. For each device, the drain current (Id) was measured as a function of source-drain voltage (Vd) for various values of gate voltage (Vg). For most devices, Vd was swept from 0 V to −50 V for each of the gate voltages measured, typically 0V, −10V, −20V, −30V, −40V, and −50V. In these measurements, the gate current (Ig) was also recorded in to detect any leakage current through the device. Furthermore, for each device the drain current was

B. Device Preparation

In order to test the electrical characteristics of the various materials of this invention, field-effect transistors were typically made using the top-contact geometry. The substrate used is a heavily doped silicon wafer, which also serves as the gate of the transistor. The gate dielectric is a thermally grown SiO₂ layer with a thickness of 165 nm. It has been previously shown for both p-type and n-type transistors that electrical properties can be improved by treating the surface of the gate dielectric. For most of the experiments described here, the oxide surface was treated with a thin (<10 nm), spin-coated polymer layer, or a self-assembled monolayer (SAM) of octadecyltrichlorosilane (OTS). Typically, an untreated oxide sample was included in the experiments for comparison.

The active layer of fused-fluorene-containing material was deposited via vacuum deposition in a thermal evaporator. The deposition rate was 0.5 Angstroms per second while the substrate temperature was held at 50° C. for most experiments. The thickness of the active layer was a variable in some experiments, but was typically 40 nm. Gold contacts of thickness 50 nm were deposited through a shadow mask. The channel width was held at 500 microns, while the channel lengths were varied between 20 and 80 microns. Some experiments were performed to look at the effect of other contact materials.

C. Device Measurement and Analysis

Electrical characterization of the fabricated devices was performed with a Hewlett Packard HP 4145b parameter analyzer. Samples were stored in vacuum, but all measurements were performed under ambient conditions.

For each experiment performed, between 4 and 10 individual devices were tested on each sample prepared, and the results were averaged. For each device, the drain current (Id) was measured as a function of source-drain voltage (Vd) for various values of gate voltage (Vg). For most devices, Vd was swept from 0 V to −50 V for each of the gate voltages measured, typically 0V, −10V, −20V, −30V, −40V, and −50V. In these measurements, the gate current (Ig) was also recorded in to detect any leakage current through the device. Furthermore, for each device the drain current was measured as a function of gate voltage for various values of source-drain voltage. For most devices, Vg was swept from 0 V to −60 V for each of the drain voltages measured, typically −30 V, −40 V, and −50 V.

Parameters extracted from the data include field-effect mobility (μ), threshold voltage (Vth), and the ratio of Ion/Ioff for the measured drain current. The field-effect mobility was extracted in the saturation region, where Vd>Vg−Vth. In this region, the drain current is given by the equation (see Sze in Semiconductor Devices-Physics and Technology, John Wiley & Sons (1981)):

$${I}_{d} = \frac{W}{2 L} μ {{C}_{ox} ( {V}_{g} - {V}_{th} )}^{2}$$

where W and L are the channel width and length, respectively, and Cₒₓ is the capacitance of the oxide layer, which is a function of oxide thickness and dielectric constant of the material. Given this equation, the saturation field-effect mobility was extracted from a straight-line fit to the linear portion of the √I_{d} versus Vg curve. The threshold voltage, Vₜₕ, is the x-intercept of this straight-line fit.

The log of the drain current as a function of gate voltage was plotted and the Iₒₙ/I_{off} ratio was extracted. The Iₒₙ/I_{off} ratio is simply the ratio of the maximum to minimum drain current over the voltage range measured.

D. Results

The following examples demonstrate that fused-fluorene-containing materials, not previously used for this application, can be used as p-channel semiconducting materials for TFTs having high mobilities and on/off ratios. The results of the examples of the present invention, along with comparative examples using known compounds, are summarized in Table 1.

### Example 1

TFTs using purified Compound 1 above as the semiconducting material were fabricated in the following manner.

A heavily doped silicon wafer with a thermally-grown SiO₂ layer with a thickness of 165 nm was used as the substrate. The wafer was cleaned for 10 minutes in a piranah solution, followed by a 6-minute exposure in a UV/ozone chamber. The cleaned surface was then treated with a self-assembled monolayer of octadecyltrichlorosilane (OTS), made from a heptane solution under a humidity-controlled environment. Water contact angles and layer thicknesses were measured to ensure the quality of the treated surface. Surfaces with a good quality OTS layer have water contact angles >90°, and thicknesses determined from ellipsometry in the range of 27 Å to 35 Å.

Purified Compound 1 was then deposited by vacuum sublimation at a pressure of 5×10⁻⁷ Torr and a rate of 0.5 Angstroms per second to a thickness of 40 nm as measured by a quartz crystal. During deposition the substrate was held at a constant temperature of 50° C. The sample was exposed to air for a short time prior to subsequent deposition of Au source and drain electrodes through a shadow mask to a 5 thickness of 50 nm. The devices made had a 500 micron channel width, with channel lengths varying from 20-100 microns.

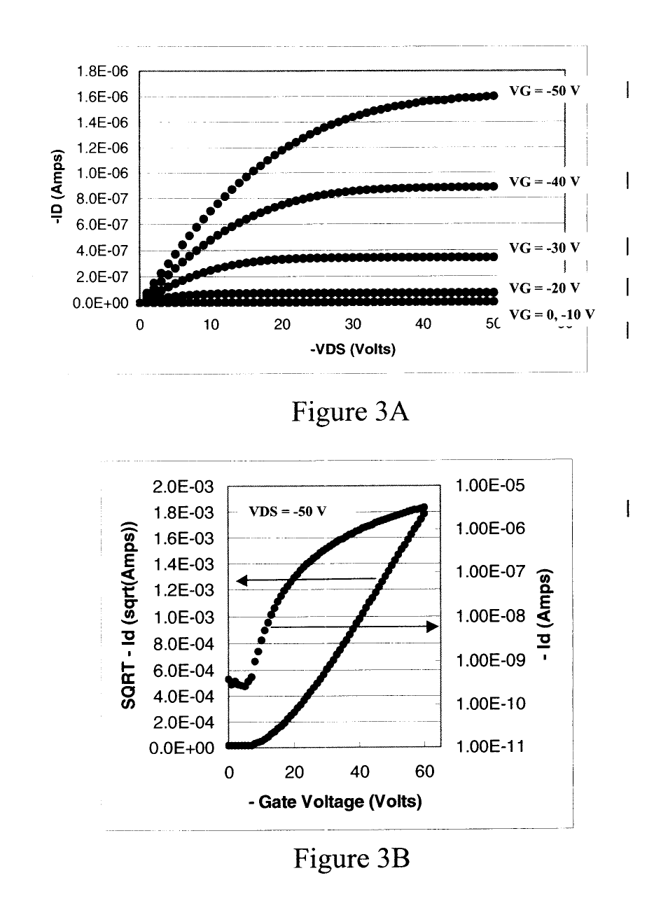

FIGS. 3A and B are graphs illustrating the electrical performance of organic thin film transistors prepared according to Inventive Example 1. FIG. 3B shows the dependence of log I_{D} on V_{G} (right y-axis) in the saturation region, when V_{D}=−50 V, for a typical transistor, with W/L=500/41. The field effect mobility, μ, was calculated from the slope of the (I_{D})^{1/2} versus V_{G} plot (left y-axis) to be 1.2×10⁻² cm²/Vs in the saturation region. The on/off ratio was 1.2×10⁴ and the threshold voltage V_{T}=−15 V. Saturation mobilities of up to 1.4×10⁻² cm²/Vs were measured from similar devices prepared in this way.

### Example 2

Samples were prepared as in Example 1, except using Compound 2 above of the present invention as the semiconducting material.

The extracted field effect mobility (μ) for devices prepared in this way was calculated to be 2.9×10⁻⁴ cm²/Vs in the saturation region. The on/off ratio was 2.1×10³ and the threshold voltage V_{T}=−37 V.

### Example 3

Samples were prepared as in Example 1, except using Compound 3 above of the present invention as the semiconducting material.

The extracted field effect mobility (μ) for devices prepared in this way was calculated to be 6.4×10⁻³ cm²/Vs in the saturation region. The on/off ratio was 1.7×10⁴ and the threshold voltage V_{T}=−64 V.

TABLE 1

| | Com- | μ | | Vₜₕ | | |
|---|---|---|---|---|---|---|
| Example | pound | (cm²/Vs) | σ (μ) | (V) | σ (Vₜₕ) | Iₒₙ/I_{off} |
| 1 | 2 | 1.3 × 10⁻² | 1.2 × 10⁻³ | −16.3 | 10.9 | 1.2 × 10⁴ |
| 2 | 4 | 2.9 × 10⁻⁴ | 9.3 × 10⁻⁵ | −37.0 | 20.3 | 2.1 × 10³ |
| 3 | 9 | 6.4 × 10⁻³ | 7.9 × 10⁻⁴ | −64.0 | 30.5 | 1.7 × 10⁴ |

### PARTS LIST

| | |
|---|---|
| 20 | source electrode |
| 28 | substrate |
| 30 | drain electrode |
| 44 | gate electrode |
| 56 | gate electrode |
| 56 | gate dielectric |
| 70 | semiconductor |

1. An article comprising, in a thin film transistor, a thin film of organic semiconductor material comprising a fused-fluorene-containing material represented by one of the following Structures (I), (II), or (III): 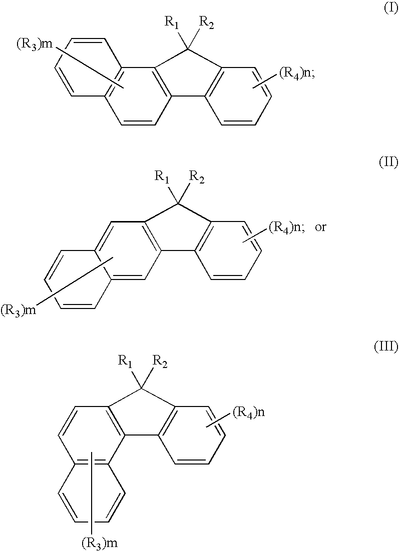
wherein:
R₁, R₂, R₃, and R₄ are optional substituents to replace corresponding ring hydrogens that are independently selected from the group consisting of hydroxy, thio, carboxy, sulfonyl, amino, alkyl, alkoxy of from 1 to 16 carbon atoms; aryl or substituted aryl of from 6 to 16 carbon atoms; heteroaryl or substituted heteroaryl of from 4 to 10 carbons; F, Cl, Br, cyano, and nitro groups; or any two adjacent R₃ substituents and/or any two adjacent R₄ substitutes can form a further aromatic ring fused to the corresponding aromatic ring in the above Structures; or R₁ and R₂ together form a cycloaliphatic ring having 3 to 6 carbons; and m is an integer from 0 to 6 and n is an integer from 0 to 4 (for example, when n is zero, the aromatic ring has four hydrogen atoms attached to four carbon ring atoms); or
wherein, in each of Structures I, II, and III, either one of R₃ or one of R₄ represents, or one of R₃ and one of R₄ each independently represents, instead of a substituent, the removal of a ring hydrogen to form, respectively, corresponding monovalent or divalent forms of Structures I, II, and III.

2. The article of claim 1 wherein the monovalent and divalent forms of Structure I, II, or III are part of oligomers comprising one or more additional units selected from monovalent or divalent Structures I, II, and III and/or one or more additional units of monovalent or divalent thiophene.

3. The article of claim 1 wherein the oligomers comprise monovalent or divalent forms of Structure I, II, or III that are serially bonded to either:
(i) one or more additional units selected from monovalent or divalent forms of Structures I, II, and III; or
(ii) one or more monovalent or divalent thiophene units; or
(iii) one or more additional units selected from monovalent or divalent forms of Structures I, II, and III and one or more substituted or unsubstituted monovalent or divalent thiophene units, in any order.

4. The article of claim 1 wherein the fused-fluorene-containing material of Structures I, II, and III are each an oligomer or non-oligomeric compound having a molecular weight of less than 2000 and comprising only 1 to 5 fused-fluorene-containing ring systems selected from Structure I, II, and III.

5. The article of claim 3 wherein the oligomer comprises one or more of same structures selected from Structure I, II, or III.

6. The article of claim 1 wherein, when an R₃ and R₄ represent the removal of a ring hydrogen to form corresponding monovalent or divalent forms, they are preferably positioned at the most terminal position of the structure along the axis of the bond joining the separated aromatic ring systems in the Structures I, II, and III.

7. The article of claim 3 wherein each of said monovalent or divalent thiophene units, if present, in the fused-fluorene-containing material of Structure I, II, and III is represented, respectively, by the following Structure IV: 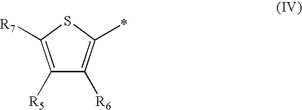
wherein each R₅, R₆, and R₇, if present, is independently hydrogen or any of the substituents mentioned for R₃ and R₄, or R₇ represents, instead of hydrogen or a substituent, the removal of a ring hydrogen to form a corresponding divalent form.

8. The article of claim 1, wherein the fused-fluorene-containing material is an oligomeric molecular compound represented by the following Structure (V): 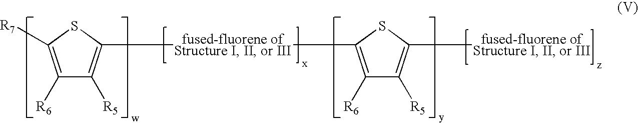
wherein each R₅, R₆, and R₇ is as defined above, that is, independently hydrogen or any of the substituents mentioned for R₃ and R₄, and wherein the fused-fluorine structures I, II, and III can be monovalent, divalent, or zero-valence, as the case may be; and wherein w is 0 to 5; x is 0 to 3, y is 0 to 5; and z is 0 to 2, so long as at least two of w, x, y, and z are not zero.

9. The article of claim 8 wherein w is 0, 1, 2, or 3; x is 1 or 2, y is 0, 1, 2, or 3; z is 0, 1, or 2; and wherein R₅ and R₆ are optional substituents to replace hydrogen that are independently selected from the group consisting of hydroxy, thio, carboxy, sulfonyl, amino, alkyl, alkoxy of from 1 to 6 carbon atoms; aryl or substituted aryl of from 6 to 14; heteroaryl or substituted heteroaryl of from 4 to 10 carbons; F, Cl, Br, cyano, and nitro groups.

10. The article of claim 1 wherein the thin film transistor further comprises first and second contact means in spaced apart contact with said thin film and third contact means spaced apart from the organic semiconductor material.

11. The article of claim 10 wherein the thin film transistor is a field effect transistor comprising an insulating layer, wherein the third contact means is a gate electrode, the first and second contact means are a source electrode and a drain electrode, and wherein the insulating layer, the gate electrode, the thin film of organic semiconductor material, the source electrode, and the drain electrode are in any sequence as long as the gate electrode and the film of organic semiconductor material both contact the insulating layer, and the source electrode and the drain electrode both contact the thin film of the organic semiconductor material, and wherein the third contact means is adapted for controlling, by means of a voltage applied to the third contact means, a current between the first and second contact means through said layer.

12. The article of claim 10 wherein said first, second and third contact means comprise, respectively, source, drain, and gate electrodes, each independently comprising a material selected from doped silicon, metal, and a conducting polymer.

13. An electronic device selected from the group consisting of integrated circuits, active-matrix display, and solar cells comprising a multiplicity of thin film transistors according to claim 1.

14. A process for fabricating a thin film semiconductor device, comprising, not necessarily in the following order, the steps of
(a) depositing, onto a substrate, a thin film of organic semiconductor material comprising organic semiconductor material that comprises a fused-fluorene-containing material of claim 1;
(b) forming a spaced apart source electrode and drain electrode, wherein the source electrode and the drain electrode are separated by, and electrically connected with said thin film of organic semiconductor material; and
(c) forming a gate electrode spaced apart from the semiconductor material.

15. The process of claim 14, wherein the compound is deposited as a film on the substrate by evaporation under vacuum or by solution-phase deposition and wherein the substrate has a temperature of no more than 150° C. during deposition.

16. The process of claim 14 wherein the organic semiconductor material comprising fused fluorene-containing material is represented by the following Structure (V): 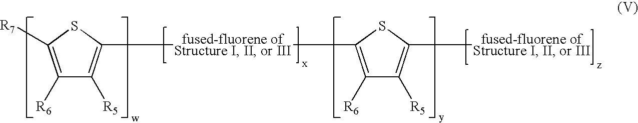
wherein each R₅, R₆, and R₇ is as defined above, that is, independently hydrogen or any of the substituents mentioned for R₃ and R₄, and wherein the fused-fluorine structures I, II, and III can be monovalent, divalent, or zero-valence, as the case may be; and wherein w is 0 to 5; x is 0 to 3, y is 0 to 5; and z is 0 to 2, so long as at least two of w, x, y, and z are not zero.

17. The process of claim 14 comprising, not necessarily in order, the following steps:
(a) providing a support;
(b) providing a gate electrode material over the substrate;
(c) providing a gate dielectric over the gate electrode material;
(d) depositing the thin film of organic semiconductor material over the gate dielectric; and
(e) providing a source electrode and a drain electrode contiguous to the thin film of organic semiconductor material.

18. The method of claim 17 wherein the support is flexible and the method is carried out in its entirety below a peak temperature of 100° C.

19. The method of claim 16 wherein the fused-fluorene-containing material is represented by the following structure: 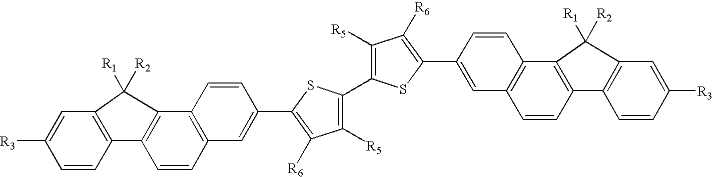
wherein R₁, R₂, R₃, R₅, and R₆ are as defined above.

20. The method of claim 16 wherein the fused-fluorene-containing material is represented by the following structure: 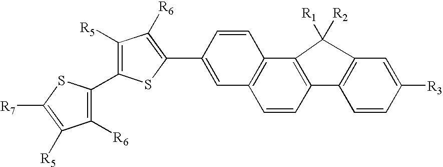
wherein R₁, R₂, R₃, R₅, and R₆ are as defined above.

21. The method of claim 19 wherein R₁ and R₂ are alkyl and R₅, R₆, and R₃ positions of the optional substituents are occupied instead by hydrogen.
